(19) United States
(12) Patent Application Publication
(10) Pub. No.: US 2006/0227504 A1
(43) Pub. Date: Oct. 12, 2006

(54) Heat-dissipating module of electronic device

(75) Inventors: Yin-Yuan Chen, Taoyuan (TW); Ren-Chun Chang, Taoyuan (TW); Chen-Yu Yu, Taoyuan (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Delta Electronics, Inc.

(21) Appl. No.: 11/302,900

(22) Filed: Dec. 14, 2005

(30) Foreign Application Priority Data
Apr. 11, 2005 (TW) 094111386

(51) Int. Cl. H05K 7/20

(52) U.S. Cl. 361/687

(57) ABSTRACT

The heat-dissipating module of the electronic device comprises a fan, a first heat-dissipating component and a second heat-dissipating component. The fan is disposed on a first side of the casing, and the first heat-dissipating component is disposed on a second side of the casing and in heat contact with the electronic components for transferring heat generated by the electronic components to the casing. The second heat-dissipating component is disposed on an outer sidewall of the casing corresponding to the first heat-dissipating component and in heat contact with a system cooling system. Thereby, the heat generated by the electronic components is transferred to the second heat-dissipating component through the first heat-dissipating component and the casing, and then dissipated by the system cooling device.

### FIELD OF THE INVENTION

The present invention relates to a heat-dissipating module of an electronic device, and more particularly to a heat-dissipating module of a power supply.

### BACKGROUND OF THE INVENTION

Power supply is an essential device for various electric appliances or information products. As known, when the power supply is operating, the electronic components included in the power supply will generate heat, which results in the increase of internal temperature of the power supply. Generally, there is one or plural heat-dissipating fans disposed on the casing of the power supply for quickly blowing the internal hot air out of the casing or introducing the external cold air into the casing for cooling down the power supply. Hence, the temperature inside the casing is decreased for preventing the electronic components from breakdown or the lifespan thereof from being shortened due to the over-temperature condition.

However, along with the technology development of the electronic products and in response to the requirements of the users, more and more electronic components are loaded on the printed circuit board (PCB) inside the power supply, resulting in the increases of the integration of the electronic components and the watt consumption of the power supply. Since the watt consumption increases, it is inevitable to increase the temperature of the whole power supply. Therefore, how to improve the heat-dissipating efficiency of the power supply is an important issue.

In the recent years, with the enhancement of the performance of the information products, such as the computer and the server, the heat generated by the electronic devices, such as CPU, in the system is increased greatly. For solving the heat-dissipation problem, the liquid cooling device has been widely used to dissipate the heat generated by the CPU. The liquid cooling device employs a circulating conduit to transfer the liquid cooled by a heat dissipator to the CPU for heat-exchange, and then the liquid at high temperature is transferred back to the heat dissipator to further dissipate the heat. The liquid cooling device has a better cooling performance and a quieter driving noise than the conventional fan, so it is an important trend to employ the liquid cooling device as the cooling system of the computer.

From the above, if the liquid cooling device of the system can be integrated with the heat-dissipating device of the power supply, or the liquid cooling device of the system can be used as an auxiliary heat-dissipating device of the power supply, the heat-dissipating efficiency of the power supply can be surely improved. Therefore, the present invention is to improve the heat-dissipating efficiency of the power supply by means of the system cooling device.

### SUMMARY OF THE INVENTION

An object of the present invention is to provide a heat-dissipating module of a power supply which comprises a heat-conducting interface disposed between the power supply and the system cooling device and served as an auxiliary heat-dissipating device of the power supply, so that partial heat generated by the power supply can be dissipated via the system cooling device to further increase the heat-dissipating efficiency of the power supply.

According to an aspect of the present invention, there is provided a heat-dissipating module of an electronic device having a casing and a plurality of electronic components disposed in the casing. The heat-dissipating module of the electronic device comprises a fan, a first heat-dissipating component and a second heat-dissipating component. The fan is disposed on a first side of the casing, and the first heat-dissipating component is disposed on a second side of the casing and in heat contact with the electronic components for transferring heat generated by the electronic components to the casing. The second heat-dissipating component is disposed on an outer sidewall of the casing corresponding to the first heat-dissipating component and in heat contact with a system cooling system. Thereby, the heat generated by the electronic components is transferred to the second heat-dissipating component through the first heat-dissipating component and the casing, and then dissipated by the system cooling device.

In an embodiment, the electronic device is a power supply.

For example, the first heat-dissipating component is a heat sink, a heat pipe or a cold plate.

For example, the second heat-dissipating component is a cold plate, a heat sink, a heat exchanger or a thermoelectric cooler.

In an embodiment, the heat-dissipating module further comprises an insulation material. For example, the insulation material is a thermal pad or an insulation tape.

The insulation material is disposed between the first heat-dissipating component and the casing, or between the casing and the second heat-dissipating component, or between the second heat-dissipating component and the system cooling device.

For example, the system is a computer, a server or an internet transmission device.

Preferably, the system cooling device is a liquid cooling device.

According to another aspect of the present invention, there is provided a heat-dissipating module of an electronic device having a casing and a plurality of electronic components disposed in the casing. The heat-dissipating module of the electronic device comprises an airflow inlet, a first heat-dissipating component and a second heat-dissipating component. The airflow inlet is disposed on a first side of the casing for an airflow provided by a system flowing therethrough into the casing. The first heat-dissipating component is disposed on a second side of the casing and in heat contact with the electronic components for transferring heat generated by the electronic components to the casing. The second heat-dissipating component is disposed on an outer sidewall of the casing corresponding to the first heat-dissipating component and in heat contact with a system cooling system. Thereby, the heat generated by the electronic components is transferred to the second heat-dissipating component through the first heat-dissipating component and the casing, and then dissipated by the system cooling device.

According to an additional aspect of the present invention, there is provided an auxiliary heat-dissipating device of a power supply having a casing and a plurality of electronic components disposed in said casing. The auxiliary heat-dissipating device of the power supply comprises a first heat-dissipating component and a second heat-dissipating component. The first heat-dissipating component is disposed on an inner sidewall of the casing and in heat contact with the electronic components for transferring heat generated by the electronic components to the casing. The second heat-dissipating component is disposed on an outer sidewall of the casing corresponding to the first heat-dissipating component and in heat contact with a system cooling system. Thereby, the heat generated by the electronic components is transferred to the second heat-dissipating component through the first heat-dissipating component and the casing, and then dissipated by the system cooling device.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic diagram showing the disposition of the present electronic device and the system cooling device;

FIG. 2 is a schematic diagram showing the heat-dissipating module of the electronic device according to a first preferred embodiment of the present invention;

FIG. 3 is a schematic diagram showing the heat-dissipating module of the electronic device according to a second preferred embodiment of the present invention;

FIG. 4 is a schematic diagram showing the heat-dissipating module of the electronic device according to a third preferred embodiment of the present invention;

FIG. 5 is a schematic diagram showing the heat-dissipating module of the electronic device according to a fourth preferred embodiment of the present invention; and

FIG. 6 is a schematic diagram showing the heat-dissipating module of the electronic device according to a fifth preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

The present invention relates to a heat-dissipating module of an electronic device. The present techniques are illustrated with the following embodiments for a power supply, but the electronic device that is applicable to the present techniques is not limited to the power supply. Any electronic device that is applicable to the following techniques is incorporated herein for reference.

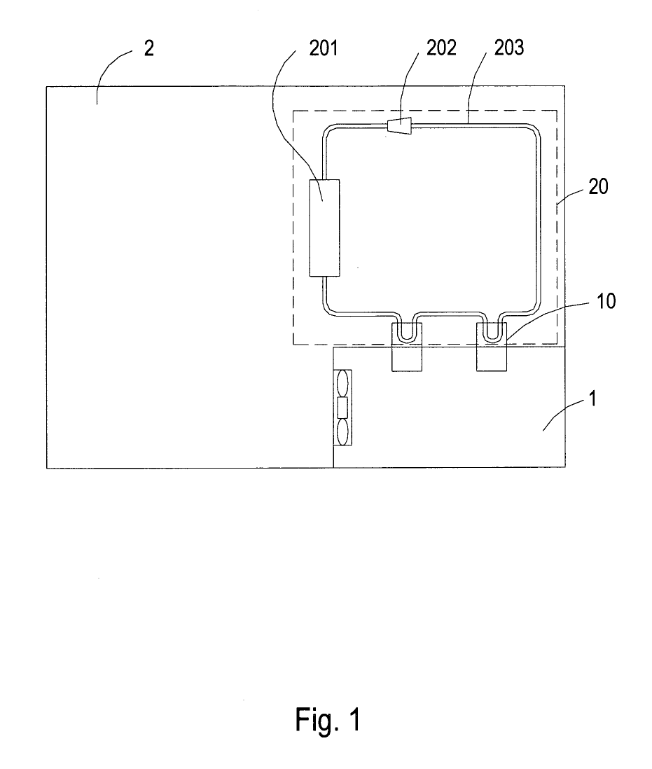

Please refer to FIG. 1, which is a schematic diagram showing the disposition of the present electronic device and the system cooling device. As shown in FIG. 1, the electronic device is a power supply 1, which is disposed in the system 2 for providing power to the system 2. The system 2 is an electric appliance, such as a computer, a server or an internet transmission device. The system 2 has a cooling device 20, preferably a liquid cooling device comprising a heat dissipator 201, a pump 202 and a conduit 203 for transferring the liquid cooled by the heat dissipator 201 to the heat-generating device, such as CPU (not shown), in the system 2 to be in heat-exchanging contact therewith, and then transferring the liquid to the heat dissipator 201 to be cooled. The idea of the present invention is to provide a heat-conducting interface 10 served as an auxiliary heat-dissipating device of the power supply 1, so that partial heat generated by the power supply 1 can be dissipated by the system cooling device 20. Certainly, the system cooling device 20 is not limited to the liquid cooling device; it can also be an air cooling device (e.g. fan) or a heat sink.

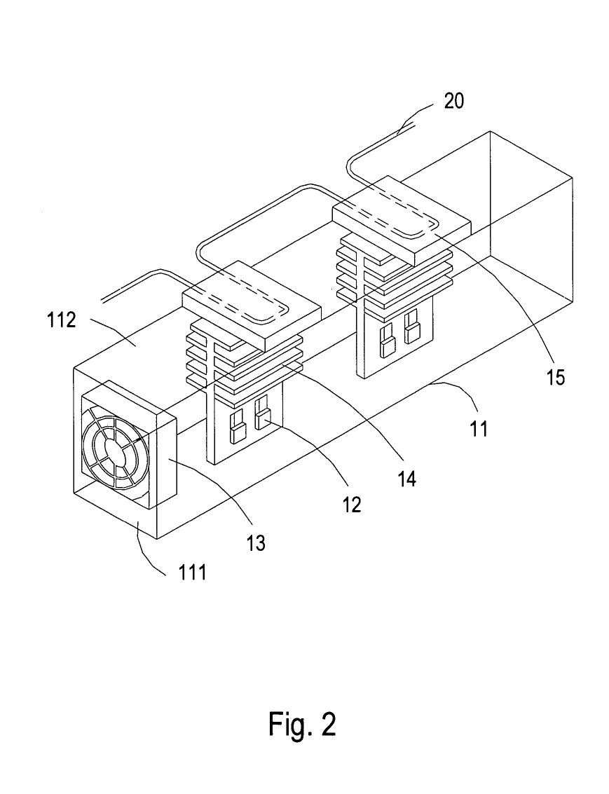

Please refer to FIG. 2, which is a schematic diagram showing the heat-dissipating module of the electronic device according to a preferred embodiment of the present invention. As shown in FIG. 2, the power supply 1 comprises a casing 11 and a plurality of electronic components 12 disposed in the casing 11. In an embodiment, the heat-dissipating module of the power supply 1 includes a fan 13 disposed on a first side 111 of the casing 11. The fan 13 is the major heat-dissipating device of the power supply 1, which is used to blow the external cold air into the casing 11 or blow the internal hot air out of the casing 11 so as to lower the temperature in the casing 11 and prevent the electronic components 12 of the power supply 1 from breakdown or the lifespan thereof from being shortened due to the over-temperature condition. In addition to the major heat-dissipating pathway provided by the fan 13, the heat-dissipating module further comprises a lateral heat-dissipating pathway relative to the airflow direction of the major heat-dissipating pathway. The lateral heat-dissipating pathway comprises a first heat-dissipating component 14 and a second heat-dissipating component 15. The first heat-dissipating component 14 is disposed on a second side 112 of the casing 11 and adjacent to the inner sidewall of the casing 11, and is in heat contact with the electronic components 12 for transferring the heat generated by the electronic components 12 to the casing 11. The second heat-dissipating component 15 is disposed on the outer sidewall of the casing 11 corresponding to the first heat-dissipating component 14 and is in heat contact with the system cooling system 20. Thereby, the heat generated by the electronic components 12 can be transferred to the second heat-dissipating component 15 through the first heat-dissipating component 14 and the casing 11, and then dissipated by means of the system cooling system 20.

In the embodiment shown in FIG. 2, the first heat-dissipating component 14 is a heat sink, the second heat-dissipating component 15 is a cold plate, and the system cooling device 20 is a liquid cooling device having a conduit extending into the cold plate to be in heat-exchanging contact with the cold plate. Certainly, the present invention is not limited to the above embodiment; any heat-dissipating component capable of effectively transferring the heat generated by the electronic components 12 to the system cooling system 20 can be employed as the heat-conducting interface of the present invention. For example, the first heat-dissipating component 14 can be a heat pipe or a cold plate, and the second heat-dissipating component 15 can be a heat sink, a heat exchanger or a thermoelectric cooler (TEC).

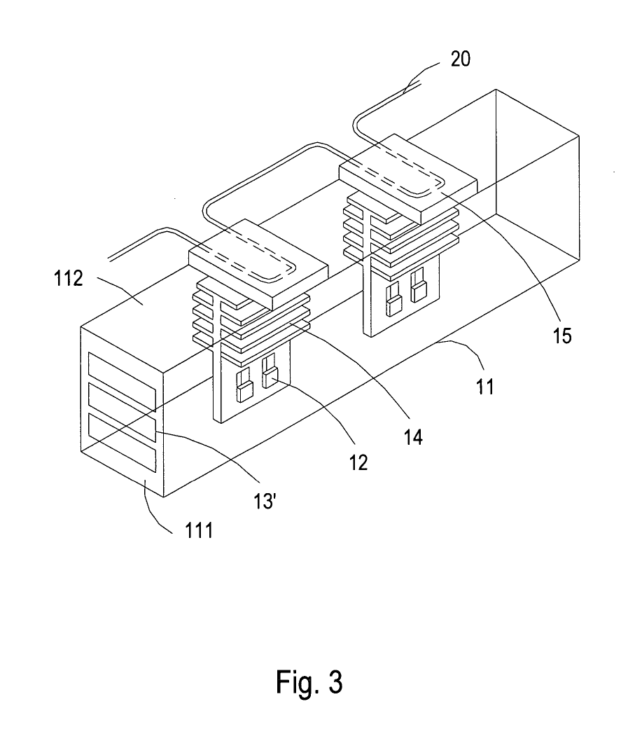

Certainly, the major heat-dissipating device of the power supply is not limited to the fan 13 disposed inside the power supply 1. Alternatively, the heat in the power supply 1 can also be dissipated by the airflow provided by the system and flowing into the power supply through an airflow inlet 13′ disposed on the first side 111 of the casing 11, as shown in FIG. 3.

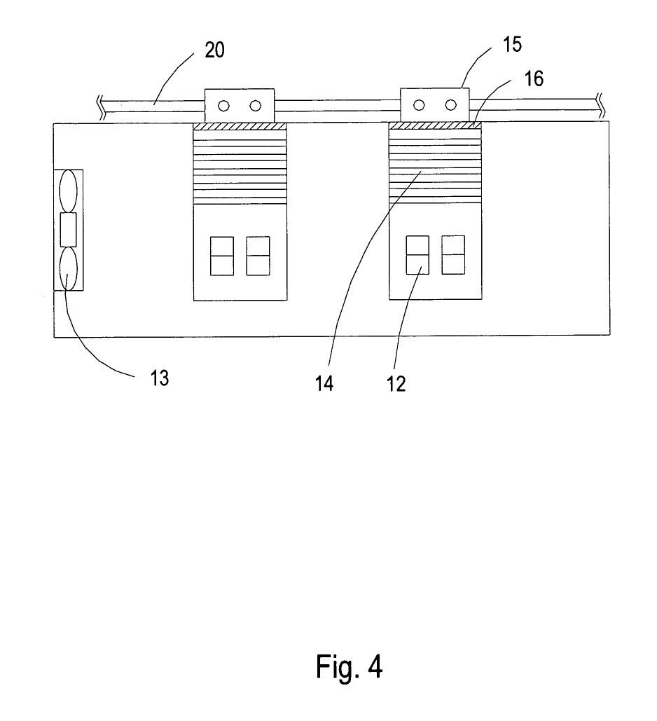

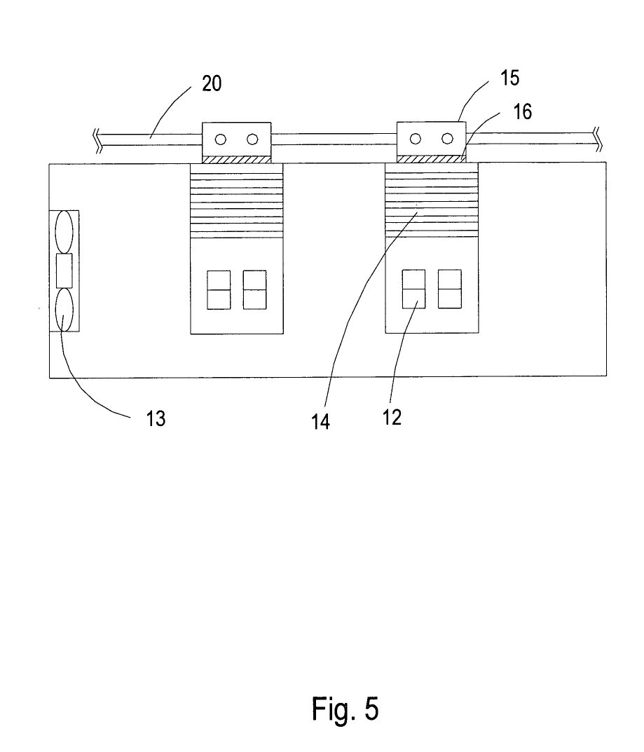

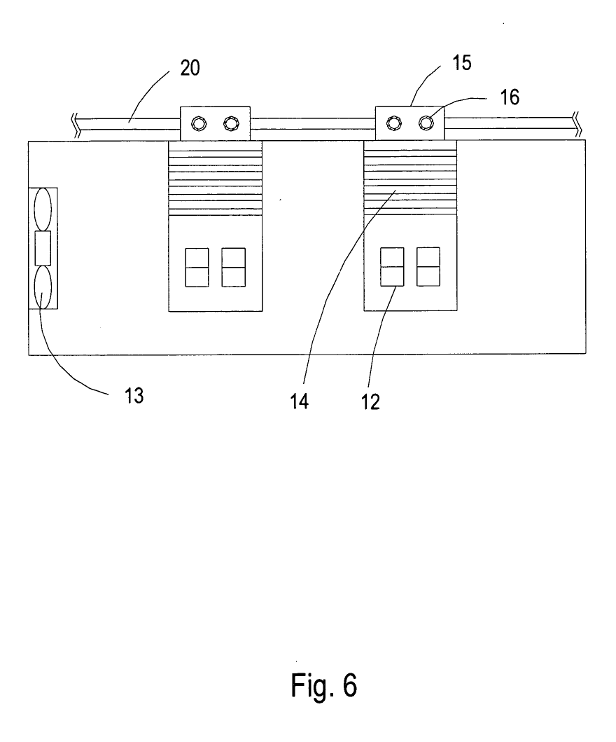

The heat-dissipating module of the power supply in the present invention further comprises an insulation material 16 for insulating the system cooling device and the power supply. The insulation material 16 is a thermal pad or an insulation tape. The insulation material 16 can be disposed between the first heat-dissipating component 14 and the casing 11 (as shown in FIG. 4), between the casing 11 and the second heat-dissipating component 15 (as shown in FIG. 5), or between the second heat-dissipating component 15 and the system cooling device 20 (as shown in FIG. 6). Besides, the liquid cooling device may have the problem of liquid leakage. If the conduit of the liquid cooling device directly extends into the power supply, a short circuit may occur when the liquid leaks out, and an irreversible damage of the power supply may be resulted in accordingly. Therefore, in the present invention, the heat-exchange interface between the system cooling device and the heat-dissipating module of the power supply is disposed on the outside of the casing of the power supply to avoid the short circuit situation caused by the liquid leakage. In addition, according to the design of the present invention, the structure of the casing needs not to be changed.

In conclusion, the present invention relates to a heat-dissipating module of a power supply. It is characterized by providing an auxiliary heat-dissipating device, which comprises a first heat-dissipating component and a second heat-dissipating component disposed on the inside and the outside of the casing respectively, to transfer partial heat generated by the power supply to the system cooling system to be heat-exchanged therewith for assisting the heat-dissipation of the power supply. Therefore, via the design of the auxiliary heat-dissipating device according to the present invention, the heat-dissipating efficiency of the power supply can be increased to avoid the damage or shortened lifespan of the electronic components in the power supply due to the over-temperature condition. In addition, under the same temperature restriction of the electronic components, the output power of the power supply can be increased. Moreover, with the action of the auxiliary heat-dissipating device, the requirement for the airflow of the fan is reduced, and thus, the noise production can be decreased. Therefore, the heat-dissipating module of a power supply of the present invention owns high industrial value.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat-dissipating module of an electronic device having a casing and a plurality of electronic components disposed in said casing, comprising:
a fan disposed on a first side of said casing;
a first heat-dissipating component disposed on a second side of said casing and in heat contact with said electronic components for transferring heat generated by said electronic components to said casing; and
a second heat-dissipating component disposed on an outer sidewall of said casing corresponding to said first heat-dissipating component and in heat contact with a system cooling system;
thereby said heat generated by said electronic components is transferred to said second heat-dissipating component through said first heat-dissipating component and said casing, and then dissipated by said system cooling device.

2. The heat-dissipating module of an electronic device according to claim 1 wherein said electronic device is a power supply.

3. The heat-dissipating module of an electronic device according to claim 1 wherein said first heat-dissipating component is a heat sink, a heat pipe or a cold plate.

4. The heat-dissipating module of an electronic device according to claim 1 wherein said second heat-dissipating component is a cold plate, a heat sink, a heat exchanger or a thermoelectric cooler.

5. The heat-dissipating module of an electronic device according to claim 1 further comprising an insulation material.

6. The heat-dissipating module of an electronic device according to claim 5 wherein said insulation material is a thermal pad or an insulation tape.

7. The heat-dissipating module of an electronic device according to claim 5 wherein said insulation material is disposed between said first heat-dissipating component and said casing.

8. The heat-dissipating module of an electronic device according to claim 5 wherein said insulation material is disposed between said casing and said second heat-dissipating component.

9. The heat-dissipating module of an electronic device according to claim 5 wherein said insulation material is disposed between said second heat-dissipating component and said system cooling device.

10. The heat-dissipating module of an electronic device according to claim 1 wherein said system is a computer, a server or an internet transmission device.

11. The heat-dissipating module of an electronic device according to claim 1 wherein said system cooling device is a liquid cooling device.

12. A heat-dissipating module of an electronic device having a casing and a plurality of electronic components disposed in said casing, comprising:
an airflow inlet disposed on a first side of said casing for an airflow provided by a system flowing therethrough into said casing;
a first heat-dissipating component disposed on a second side of said casing and in heat contact with said electronic components for transferring heat generated by said electronic components to said casing; and
a second heat-dissipating component disposed on an outer sidewall of said casing corresponding to said first heat-dissipating component and in heat contact with a system cooling system;
thereby said heat generated by said electronic components is transferred to said second heat-dissipating component through said first heat-dissipating component and said casing, and then dissipated by said system cooling device.

13. An auxiliary heat-dissipating device of a power supply having a casing and a plurality of electronic components disposed in said casing, comprising:
a first heat-dissipating component disposed on an inner sidewall of said casing and in heat contact with said electronic components for transferring heat generated by said electronic components to said casing; and
a second heat-dissipating component disposed on an outer sidewall of said casing corresponding to said first heat-dissipating component and in heat contact with a system cooling system;
thereby said heat generated by said electronic components is transferred to said second heat-dissipating component through said first heat-dissipating component and said casing, and then dissipated by said system cooling device.

14. The heat-dissipating module of an electronic device according to claim 13 wherein said first heat-dissipating component is a heat sink, a heat pipe or a cold plate.

15. The heat-dissipating module of an electronic device according to claim 13 wherein said second heat-dissipating component is a cold plate, a heat sink, a heat exchanger or a thermoelectric cooler.

16. The heat-dissipating module of an electronic device according to claim 13 further comprising an insulation material.

17. The heat-dissipating module of an electronic device according to claim 16 wherein said insulation material is a thermal pad or an insulation tape.

18. The heat-dissipating module of an electronic device according to claim 16 wherein said insulation material is disposed between said first heat-dissipating component and said casing.

19. The heat-dissipating module of an electronic device according to claim 16 wherein said insulation material is disposed between said casing and said second heat-dissipating component.

20. The heat-dissipating module of an electronic device according to claim 16 wherein said insulation material is disposed between said second heat-dissipating component and said system cooling device.
